(19) United States
(12) Patent Application Publication
(10) Pub. No.: US 2009/0056805 A1
(43) Pub. Date: Mar. 5, 2009

(54) Photovoltaic Thin-Film Solar Cell and Method Of Making The Same

(75) Inventors: Allen M. Barnett, Landenberg, PA (US); Jeffrey Barnett, Landenberg, PA (US); Kevin Allison, Goleta, CA (US); Jerome S. Culik, Nottingham, PA (US)

Correspondence Address: KILYK & BOWERSOX, P.L.L.C., 400 HOLIDAY COURT, SUITE 102, WARRENTON, VA, 20186, US

(73) Assignee: BLUE SQUARE ENERGY INCORPORATED, North East, MD (US)

(21) Appl. No.: 12/199,883

(22) Filed: Aug. 28, 2008

Related U.S. Application Data
(60) Provisional application No. 60/968,443, filed on Aug. 28, 2007.

(51) Int. Cl. H01L 31/042; B05D 5/12

(52) U.S. Cl. 136/256; 427/74

(57) ABSTRACT

A photovoltaic device having a front and back orientation and comprising: a crystalline substrate having a resistivity greater than about 0.01 ohm-cm; and an epitaxy thin-film layer in front of said substrate, said thin-film layer contacting said substrate in at least one region to define a p-n junction.

This application claims the benefit under 35 U.S.C. §119(e) of prior U.S. Provisional Patent Application No. 60/968,443, filed Aug. 28, 2007, which is incorporated in its entirety by reference herein.

### BACKGROUND

The photovoltaic (PV) cell industry has followed essentially two paths-bulk silicon, and, more recently, thin-film crystalline silicon. Single-crystal and multi-crystalline bulk silicon solar cells have demonstrated high efficiency and long operating lifetimes, but have been too costly for many applications due to their high material demands and low manufacturing throughput. Thin-film technologies were developed as a means of substantially reducing the cost of photovoltaic (PV) systems. Thin-film processes are appealing due to reduced materials consumption and the potential for high-throughput production. They are also amenable to monolithic array designs, thus reducing costs of creating modules. Unfortunately, thin-film crystalline silicon solar cells have generally failed to demonstrate the degree of efficiency or reliability found in bulk crystalline silicon solar cells.

In the 1980s, the technology evolved to hybrid approaches in which thin-films of silicon were deposited on low-cost substrates. This approach combines the high efficiency and reliability associated with bulk crystalline silicon solar cells with the low-cost potential of thin-film deposition technology. U.S. Pat. No. 4,571,448, granted to Allen Barnett (also present applicant), discloses a seminal design for a thin-film crystalline silicon photovoltaic solar cell on particular types of low-cost substrates. This patent realized that incorporating light-trapping features in thin-film solar cells not only ameliorates inefficiencies previously expected with thin-film silicon solar cells, but also enhances performance of the thin-film cells beyond traditional bulk silicon approaches. Many of the expected advantages of a thin-film silicon solar cell, such as high photogenerated currents due to light-trapping, high voltages due to higher doping levels, monolithic interconnection, reduced sensitivity to impurities and crystal defects, and enhanced gettering potential, have been demonstrated, but only singularly in various experimental devices.

Unfortunately, the useful and synergistic combination of these features in a cost-effective, production technology has eluded the industry. The Applicants have previously recognized, in International Published Application No. WO 2006/29834, that the problems encountered in achieving this objective tended to involve difficulties in producing thin layers of high quality silicon on low-cost substrates. This reflects conventional wisdom that the key to robust and effective PV cells lies in the quality of the thin film.

Therefore, there is a need to provide a thin film crystalline silicon PV cell design that not only offers the benefits of thin-film and light trapping technologies, but also is robust and inexpensive. The present invention fulfills this need among others.

All publications, including patents and applications, mentioned herein are incorporated in their entirety by reference herein.

### SUMMARY OF INVENTION

The present invention provides a low-cost, robust, high-efficiency PV cell that overcomes the shortcomings of the prior art by accommodating the defects of the thin-film layer, rather than attempting to eliminate them. Specifically, applicant has discovered that the performance of a thin-film PV cell can be improved remarkably and surprisingly by increasing the resistance of the substrate to prevent defects in the thin-film layer from causing shunts. In other words, the substrate is made “fault tolerant” to accommodate the thin-film layer. This is a significant departure from conventional approaches of improving the quality of the thin films, and recognizes instead that a commercially-viable PV cell must be capable of high-volume production in which defects in the thin-film layer, such as manufacturing variances, voids, defects, stacking faults, inclusions and impurities are unavoidable as a practical matter. Furthermore, the detrimental effects of these defects would likely increase as the layer becomes thinner to enhance performance or less uniform due to high-volume manufacturing (i.e., relaxed tolerances). The substrate of the present invention, however, allows this enhanced performance and high-volume manufacturing to be realized while accommodating the associated defects.

This enhanced performance more than compensates for the reduced voltage across the cell due to the substrate's increased resistivity. That is, although increasing the substrate's resistivity tends to diminish voltage across the PV cell, the applicant has found that significant fault tolerance can be realized without a corresponding decrease in solar cell voltage. Typically, substrate resistivity can be increased significantly without a precipitous decline in voltage.

In addition to improved performance, the PV cell of the present invention also provides significant cost savings. Specifically, the specified resistivity of the substrate generally correlates to a less pure substrate. This relatively impure subtract material is less expensive since less refining of the semiconductor is required. For example, the desired resistivity may correspond to a boron concentration in silicon of greater than 10 ppm, which is relatively impure and thus readily achievable using inexpensive purification processes. Not only is the material cost low, but also the substrate can be manufactured using casting processes, rather than complex and slow Czochralski or Float Zone ingot formation processes. The thin-film layer also is less expensive since it can be made thinner, thus reducing processing time and material requirements. Additionally, the fault tolerance of the substrate allows the thin-film layer to be formed with processes that are quicker and less expensive even though they may tend to introduce more defects (e.g., manufacturing variances/defects/crystal boundaries) compared to traditional epitaxial vapor deposition techniques.

The performance of the PV cell of the present invention is further enhanced by the addition of light-capturing elements, such as reflectors and textured surfaces, and by concentrating the charge carriers using barrier layers to reduce the size of the p-n junctions. To this end, applicant recognizes that epitaxial lateral overgrowth (ELO) techniques, which were developed in the production of microelectronic devices, may be applied to PV cells to enable the thin-film layer to be grown over planar reflective or barrier layers on the substrate. By using ELO processes to incorporate reflective surfaces and other light-capturing elements into a PV cell, enhancements, such as high photogenerated currents, improved photon conversion, and enhanced gettering potential, are synergistically realized.

Accordingly, one aspect of the present invention is a PV cell having a thin-film, epitaxially grown layer overlaying a fault resistant substrate. The cell can comprise a crystalline substrate having a resistivity of 0.01 ohm-cm or greater, such as 0.02 ohm-cm to about 0.5 ohm-cm, and a thin-film layer(s), such as an epitaxy thin-film layer, on said substrate. The thin-film layer can contact the substrate in at least one region to define a p-n junction. The PV cell can have improved efficiency, such as through the use of reflectors and/or other light capturing optics. For example, reflectors between the substrate and the thin-film layer can improve the conversion of photons to charge carriers which can be transported across the p-n junction.

Another aspect of the present invention is a method of manufacturing a PV cell by forming a thin-film layer (e.g., such as an epitaxially grown layer(s)) on a fault-tolerant substrate. The method can comprise providing a crystalline substrate having a resistivity of at least 0.01 ohm-cm (e.g., such as greater than 0.02 ohm-cm), and forming a thin-film layer(s), such as epitaxially depositing a thin-film layer, over at least a portion of said substrate. The method can further comprise depositing a reflector between the substrate and the thin-film layer and using epitaxial lateral overgrowth processes (or other processes) to cover the reflector with the thin-film layer.

### BRIEF DESCRIPTION OF DRAWINGS

FIG. 1 shows a perspective, schematic view of an embodiment of a photovoltaic device.

FIG. 1a is a detailed view of a portion of the device of FIG. 1.

FIG. 2 shows a plan view of an embodiment of a photovoltaic device.

FIG. 3 shows a cross section of a portion of the device of claim 2.

FIGS. 4A-4F show a series of cross-sections illustrating a process for making a photovoltaic device.

FIG. 5 is a micro-photograph of a PV device of the present invention.

FIG. 6 is a micro-photograph showing a defect etched epitaxial layer.

FIG. 7 is a micro-photograph showing a surface of an etched sample with low defect density.

FIG. 8 is a micro-photograph showing a surface of an etched sample with high defect density.

FIGS. 9 and 10 are micro-photographs showing ELO growth on a p-type substrate.

### DETAILED DESCRIPTION OF INVENTION

The present invention relates to a photovoltaic device, as well as components thereof, and methods to make the device, as well as components thereof.

The present invention, in part, relates to a photovoltaic device having a substrate. The photovoltaic device can have a thin-film layer or layers on the substrate. This thin-film layer is a semiconductor thin film layer. The thin-film layer can be in direct contact with the substrate or can be separated or partially separated from the substrate by one or more layers located between the substrate and the thin-film layer. A p-n junction is established between the thin-film layer and the substrate. In the present invention, the substrate has a resistivity of 0.01 ohm-cm or greater. The resistivity can be from about 0.01 ohm-cm to about 2 ohm-cm. This resistivity can be greater than 0.01 ohm-cm, such as from 0.02 ohm-cm to less than 1 ohm-cm. Other ranges include, but are not limited to, from 0.02 to 0.5 ohm-cm, from 0.02 to 0.8 ohm-cm, from 0.03 to 0.6 ohm-cm, from 0.04 to 0.5 ohm-cm, from 0.04 to 0.2 ohm-cm, from 0.05 to 0.4 ohm-cm, from 0.05 to 0.2 ohm-cm, from 0.06 to 0.35 ohm-cm, from 0.05 to 0.25 ohm-cm, from 0.07 to 0.1 ohm-cm, from 0.1 to 0.2 ohm-cm, or from 0.05 to 0.15 ohm-cm. These ranges can be specific or can be approximate. The resistivity mentioned herein can be measured by the Four Point Probe method. The test standard-SEMI MF84 can be used. The substrate is a p-type or n-type material, such as a p+-type material.

The substrate can be a crystalline substrate. The substrate can have a variety of purities. The substrate can be any thickness and have any dimensions or geometrical shape. Preferably, the substrate is square, semi-square or rectangular, but can be other geometrical shapes based on the desired solar cell configurations. The thickness of the substrate can be any suitable thickness that permits the solar cell to convert solar energy into electricity by at least a photovoltaic effect. Examples of suitable thicknesses for the substrate include, but are not limited to, about 100 microns or higher, 100 microns to 800 microns, about 150 to 250 microns. Other ranges within or outside these ranges can be used. The substrate can be any material that can provide the resistivity levels mentioned herein and which supports the epitaxial growth on the substrate as described herein. For instance, the substrate can be a semiconductor material. As an example, the substrate can be a silicon-containing material. For example, the substrate can primarily contain and be made of silicon. For instance, the substrate can be a relatively high purity silicon containing substrate. For instance, the substrate can be a substrate that is at least 99.9 wt % silicon material, wherein the purity % is with respect to the by weight purity of the recited element. In other words, a 99.9 wt % Si substrate would mean that there are 1,000 ppm (by wt) impurities present that are not silicon. These impurities can be gaseous, metallic, and/or non-metallic elements. The impurities can be exclusively non-gaseous and/or can exclusively be metallic impurities and/or can exclusively be non-metallic impurities, or a combination of one or more of these groups. The substrate can be a silicon substrate having a purity of at least 99.95 wt % Si, or at least 99.99 wt % Si, or at least 99.995 wt % Si, or at least 99.999 wt % Si. Purity ranges for the substrate can include, but are not limited to, a Si substrate having a purity of from 99.95 wt % Si to 99.999 wt % Si, from 99.95 wt % Si to 99.995 wt % Si, from 99.95 wt % Si to 99.99 wt % Si, from 99.99 wt % Si to 99.9999 wt % Si or purer, as well as other ranges within or outside of these ranges. These purities are acceptable as long as the stated resistivity of the substrate is present. Besides Si, the substrate can be any semiconductor material, such as, silicon-germanium alloys, silicon-containing alloys, or any combination thereof, and optionally have the same purity ranges for the primary semiconductor material.

With respect to the type of impurities that can be present in the substrate, in general, the purities can be of any type, as mentioned above, as long as the resistivity of the substrate is achieved. For instance, the substrate with respect to a Si substrate, can have the following impurities present and can have the impurity levels for that respective element as shown below (ppm based on weight), though other impurity levels can be present, as well as other impurities not specifically mentioned herein:
Group III A element(s) like Boron: e.g., 1-20 ppm, such as 1-10 ppm, 2-15 ppm, 5-15 ppm.
Group V A element(s) like Phosphorus: e.g., 1-20 ppm, less than 20 ppm, less than 10 ppm, less than 5 ppm, 1-10 ppm.
   Iron: e.g., 5 ppm or less, 4 ppm or less, 3 ppm or less, 2 ppm or less, 1 ppm or less, 0.1 ppm to 2 ppm.
   Aluminum: e.g., 5 ppm or less, 4 ppm or less, 3 ppm or less, 2 ppm or less, 1 ppm or less, 0.1 ppm to 2 ppm.
   Carbon: e.g., 5 ppm or less, 4 ppm or less, 3 ppm or less, 2 ppm or less, 1 ppm or less, 0.1 ppm to 2 ppm.
   Oxygen: e.g., 5 ppm or less, 4 ppm or less, 3 ppm or less, 2 ppm or less, 1 ppm or less, 0.1 ppm to 2 ppm.
   Chromium: e.g., 5 ppm or less, 4 ppm or less, 3 ppm or less, 2 ppm or less, 1 ppm or less, 0.1 ppm to 2 ppm.
   Calcium: e.g., 5 ppm or less, 4 ppm or less, 3 ppm or less, 2 ppm or less, 1 ppm or less, 0.1 ppm to 2 ppm.
   Sodium: e.g., 5 ppm or less, 4 ppm or less, 3 ppm or less, 2 ppm or less, 1 ppm or less, 0.1 ppm to 2 ppm.
   Titanium: e.g., 5 ppm or less, 4 ppm or less, 3 ppm or less, 2 ppm or less, 1 ppm or less, 0.1 ppm to 2 ppm.

With respect to the impurities identified above, it is to be understood that these impurity levels not only include the elemental form of the impurity, but also the oxide form, carbide form and/or nitride form of the elements, excluding oxygen, carbon, and nitrogen. Further, with respect to any other element not listed above, each of these non-listed elements can be present, for instance, in an amount of 1 ppm or less, such as 0.1 ppm to 1 ppm, or 0.001 ppm to 1 ppm, or 0.0001 ppm to 1 ppm for each element. These other non-mentioned elemental impurities that can be present can be non-detectable. Further, the combined Group III A elements can have a combined total impurity amount of 20 ppm or less, such as 1-20 ppm, 1-10 ppm, 2-15 ppm, 5-15 ppm, 1-5 ppm, or 5-10 ppm. All ppms stated herein are by weight unless stated otherwise. Further, for a Si substrate for instance, the Group IV A elements (excluding Si) can be present in an amount of 5 ppmw or less, collectively, 1 ppmw or less, or 0.1 to 1 ppmw. Preferably, the Group III A element present, which favorably contributes to the desired resistivity is boron alone, or boron combined with one or more other Group III A elements, or one or more Group III A elements without boron. Further, it is pointed out that silicon, when used as a substrate, can have high boron and high phosphorus contents, and with the present invention, since a high amount of boron can be present due to the desire to have the stated resistivity levels, this resistivity can be achieved, for instance, by removing phosphorus from the silicon substrate, which is more easily removed than boron, and by removing the particular atomic amount of phosphorus, a sufficient balance of boron to phosphorus exists on an atomic level, thus achieving the desired resistivity levels. With the present invention, the desired resistivity levels can be achieved in the substrate, for instance, by removing a majority of the phosphorus such as to non-detectable limits, and then leaving enough boron present to achieve the desired resistivity or, a balance on an atomic level can be achieved between boron and phosphorus such that there is a sufficient amount of boron to create the desired resistivity level stated herein. Also, as an alternative, one, of course, could start with very pure silicon substrate or other substrate material and add dopants to achieve the desired resistivity levels as stated herein. It is to be understood that with respect to the above impurity levels, the Group III A impurity levels are present and the remaining impurity levels identified above, other than boron or other than the Group III A elements, are optional and one or more of these elements can be present, for instance at the stated limits or be removed to non-detectable limits though unnecessary. With the present invention, the substrate can have any one, two, three, four, five, six, seven, eight, or nine of the identified impurities (other than the Group III A element) as an option, and it is noted that these impurity levels are considered extremely high with respect to silicon semiconductor technology and yet with the present invention, a working photovoltaic device can be obtained with one or more of these high impurity levels as an option. The Group III A elements include boron, aluminum, gallium, and indium, or any combination thereof. It is noted that the Group III A element can be more abundant on an atomic level than the Group V A elements on an atomic level. Thus, as a preferred embodiment, the boron is generally present in higher atomic levels than the Group V A (e.g., phosphorus content) on an atomic level.

Generally, the resistivity of the substrate for purposes of the present invention is achieved by having certain impurities present in the substrate. These impurities can be added as dopants to the material that forms the substrate to achieve the resistivity and/or can be present in the substrate as an impurity and refined/purified to the extent necessary to achieve the desired impurity levels (total overall impurities and particular impurity levels for certain elements) and thus achieve the desired resistivity levels. For instance, one way to achieve the desired resistivity of the present invention for the substrate is the presence of certain amounts of boron. Boron is naturally found in silicon as an impurity and is generally removed in many semiconductor applications at great expense. With the present invention, the amount of boron can be, for instance, as shown above. With the present invention, the material forming the substrate, such as silicon, can be subjected to certain conventional purification or refining methods such that the boron that remains has the particular levels, for instance, as stated above, to achieve the desired resistivity of the present invention. Thus, with the present invention, the impurities present in the substrate that is used can be added intentionally or it can be found naturally in the product and the substrate is subjected to standard purification techniques to remove any unwanted impurities that would affect the desired resistivity range of the overall substrate. Instead of boron, other Group III A impurities can be used to achieve the desired resistivity or a combination of one or more of these elements can be used to achieve the resistivity of the present invention. The charge balance of phosphorus and boron can be called “compensation.” Most simply: one B atom plus one P atom results in neutral charge. Two B atoms plus one P atom results in the charge of one B atom. In practice, the relationship between B and P can be affected by electrical state and/or compounding of impurities with other elements such as O or C.

The substrate used herein with the present invention is a solid material. For instance, the solid substrate can be an ingot-derived material, a powder-metallurgy material, or a sintered or consolidated material. For example, with respect to a silicon substrate, the silicon can be formed into a substrate by melting and directionally solidifying the silicon to form an ingot or other casted object, such as in the shape of the substrate as a plate, rod, billet, or the like. The silicon may be melted and re-crystallized to form a single crystal ingot of silicon. The substrate, such as a Si substrate, can be formed by consolidating silicon powder in a powder metallurgy process to form a desired substrate shape or to form an intermediate shape that is subjected to deformation techniques in the same manner as ingot-derived material. In the alternative, the substrate, such as a silicon substrate, can be a sintered material where, for instance, silicon powder is sintered together to form a desired substrate shape.

The substrate of the present invention can be a single continuous substrate or can be formed from two or more layers of substrate material which can be the same or different as long as the overall substrate has the desired resistivity as mentioned herein. Further, the surface of the substrate that receives the thin-film layer or that is in contact with the thin-film layer can be a continuous surface or can be a collection of two or more substrates that are joined together to permit the substrate to serve as a substrate for a solar cell, as long as the overall device converts solar energy into electricity by a photovoltaic effect.

The substrate can be monocrystalline or multi-crystalline. The substrate can have a range of grain sizes and/or crystallographic orientations (also known as crystal texture). For instance, the silicon or other bcc-type material can have a (100), (111), (110), or other (xyz) orientations present in the substrate. The substrate can have a primary orientation of one of these crystallographic orientations or can have a combination of two or more. The crystallographic orientation can be random. The substrate, if multi-crystalline, can have any grain size with respect to the material present, such as a grain size of greater than about 1 millimeter. A preferred grain size is greater than 10 millimeters, such as 10 to 125 mm or 5 to 20 mm, wherein the grain size is an average grain size.

The upper surface of the substrate can be smooth or textured (e.g., to a depth ranging from 1 micron to 10 microns) to have any textured shape or design to receive a thin-film layer. For instance, the texture can have the following designs: random pyramidal, grooved pattern, polished, random porous, uniform pillowed relief, random pitted relief, and/or random inverted pyramidal.

The substrate mentioned herein, as stated, forms the substrate for a solar cell or photovoltaic cell, or PV device. The photovoltaic device can have one or more layers placed on the substrate as mentioned herein. The photovoltaic device can have at least one thin-film layer, as stated above, which is a semiconductor layer. This thin-film layer can be an epitaxial thin-film layer that is a p-type thin-film layer or a n-type thin-film layer, depending upon what the substrate is. This layer can be formed by chemical vapor deposition or other techniques. If the substrate is a p-type material, then the semiconductor thin-film is n-type and vice versa. The substrate can be the only p-type source or layer in the overall PV device. Similarly, as an option, the semi-conductor thin film layer can be the only n-type source or layer in the PV device. The opposite can also be true, where the substrate can be the only n-type source or layer in the overall PV device and/or the semi-conductor thin film layer can be the only p-type source or layer. As stated above, a p-n junction is formed from the substrate and thin-film layer. Other layers can be present on the thin-film layer as described below and these include conventional layers, such as described in U.S. patent application Ser. No. 12/066,960, incorporated in its entirety herein. Details of the substrate, thin layer, and optional layers are described further below and can be present. With the device of the present invention, the substrate can be the sole p-type layer or n-type layer in the device. Put another way, if the substrate is the p-type provider, this is sufficient and no additional p-type layers are needed, though they can be optional. Similarly, if the substrate is the n-type provider, then no additional n-type layers are needed, though they can be optional.

In the present invention, the photovoltaic device can have one or more of the following properties and preferably has all of these properties, two or more of these properties, three or more of these properties, or four or more of these properties:

(a) Energy Conversion Efficiency: up to 23%, 5% to 23%, 10% to 20%

(b) Open Circuit Voltage (V_{OC}): up to 780 mV, such as 300 mV to 780 mV, 400 mV to 780 mV, 580 mV to 780 mV

(c) Short Circuit Current Density (J_{SC}): up to 42 mA/sq cm, such as 10 to 42 mA/sq cm, 15 to 35 mA/sq cm, 23 mA/sq cm to 42 mA/sq cm

(d) Reflectance (%): up to 15%, 0.5% to 15%, 10% to 15%, 5% to 15%

(e) Fill Factor: up to 83%, from 50% to 83%, or 65% to 83%

(f) Fault Tolerance/Tolerant: discussed below.

With respect to the above properties, the following standards are used to measure the properties identified above: ASTM E948 (9.5.1 (lsc), 9.5.2 (V_{OC}), 9.5.5 (FF), 9.5.6 (Efficiency)). Reflectance is defined as AM1.5 solar weighted average of the spectral reflectance, using the solar spectral irradiance specified in ASTM G-173-03.

With respect to the thin-film layer (e.g. the epitaxial semiconductor layer), the thin-film layer present on the substrate can have flaws such as stacking faults, dislocations, and/or point defects, and/or voids. Voids may also be known as pin holes. The flaws that can be present on the thin-film layer and yet achieve an operable photovoltaic cell, such as one which has any one or more of the above-identified (or two or more, three or more, four or more, or all) properties, can be as follows: from 1 flaw per sq cm up to 5×10⁶ flaws per sq cm as measured by preferential etch and visual inspection as described in SEMI M62, DIN 50434, JIS H 0609. Other examples of acceptable flaws in the crystalline semiconductor thin-film, which can be epitaxial grown, include, but are not limited to: 2 to 750,000 flaws/cm²; 5 to 500,000 flaws/cm²; to 100,000 flaws/cm²; 100 to 75,000 flaws/cm²; 1,000 to 50,000 flaws/cm²; 3,000 to 50,000 flaws/cm²; 5,000 to 50,000 flaws/cm²; 10,000 to 50,000 flaws/cm²; over 5,000 flaws/cm², and the like. From an electrical circuit analysis, it is known that pin holes and other structural defects behave as shunt resistors or shunt diodes in parallel with the base diode. These flaws lead to reduced voltage. This flaw range and the ability of the PV device to operate is what make the PV device fault tolerant.

The flaws can be present on the thin-film layer in a random or uniform manner across the entire thin-film layer surface or can be concentrated in one or more regions or can have different concentrations throughout the thin-film surface layer.

After growing or casting and slicing into wafer form (or growing in wafer form, the substrate can be damage etched, for instance, by using a dilute alkaline solution, for example, a solution containing from 20%-40% by weight mixture of NaOH or KOH in H₂O at a temperature range of 70-120 Degrees Celsius. The alkaline solution can be neutralized using a liquid solution of HCl. The thin native silicon oxide layer can be removed, such as by using an acid, e.g., a dilute HF acid solution containing from 1% to 10% by volume HF in H₂O.

The thin film can be formed by a CVD reaction which employs resistive, infra-red, radio frequency, or any combination of the three heating methods at a pressure range, for instance, of 50-900 Torr. Before depositing the thin film layer, native oxide can be removed, such as by a hydrogen reduction which can occur from 1150-1250 Degrees Celsius, for instance, at a pressure of 50 Torr-900 Torr. Native oxide can be removed in-situ and micro-cracks on the surface of the substrate can be polished down, such as by using an etch gas mixture, such as one containing 0.5%-3% HCl gas in H₂, for instance, at a temperature range of 1150-1250 degrees Celsius at a pressure of 200-900 Torr. The thin film deposition can occur using SiH₄, SiH₂Cl₂, SiHCl₃, SiCl₄, or any combination of the stated silicon containing gas with a volume % range of 0.5%-10% in H₂ diluent gas with a corresponding growth rate from 0.5-5.0 microns per minute and thickness of 2-50 microns as measured by the Angle Lapping and Staining Technique (SEMI MF110) or the Infrared Dispersive Technique (SEMI MF95). Resistivity of the thin film layer can be tuned to a range of 0.5-10 ohm cm as measured by the Four Point Probe Method for Epitaxial Layers (SEMI MF374) or the Spreading Resistance Probe Method (SEMI MF525, SEMI MF 672). Charge/type and resistivity of the thin film layer as measured herein can be controlled by the addition of PH₃ (N-type) and B₂H₆ (P-type). The resistivity of the epitaxial layer may vary from the surface adjacent the substrate to the top or upper surface of the epitaxial layer. For example, the resistivity can be lower at the surface adjacent the substrate, such as from 0.05 ohm cm to 0.5 ohm cm and gradually increase toward the top surface. Alternatively, the resistivity of the epitaxial layer can be lower at the top surface, from 0.001 ohm cm to 0.5 ohm cm and gradually decrease toward the substrate. Any combination of above stated resistivity profile may be used as measured by the Spreading Resistance Probe Method (SEMI MF 672).

With the present invention, the thin-film layer (e.g. epitaxially grown semiconductor layer) does not need to be recrystallized, but can be. The semiconductor thin layer can be unrecrystallized after it is formed on the substrate and/or other layer. Due to the preferred manner of forming the thin layer, epitaxial formation, a crystalline thin layer is formed. Preferably, this layer is formed by an epitaxial lateral overgrowth (ELO) method as described in more detail below. Methods of ELO as described in Rathman et al., Lateral Epitaxial Overgrowth of Silicon on SiO₂, JOURNAL OF THE ELECTROCHEMICAL SOCIETY, October 1982, pp. 2303-2306, can be used herein, and is incorporated in its entirety herein by reference. The recrystallization, if done, can be partial or nearly complete, or entirely complete, such as at least 95% recrystallization, at least 99% recrystallization, or 100% recrystallization. The thin-film layer can be even or uneven with respect to the thickness of the layer on the substrate.

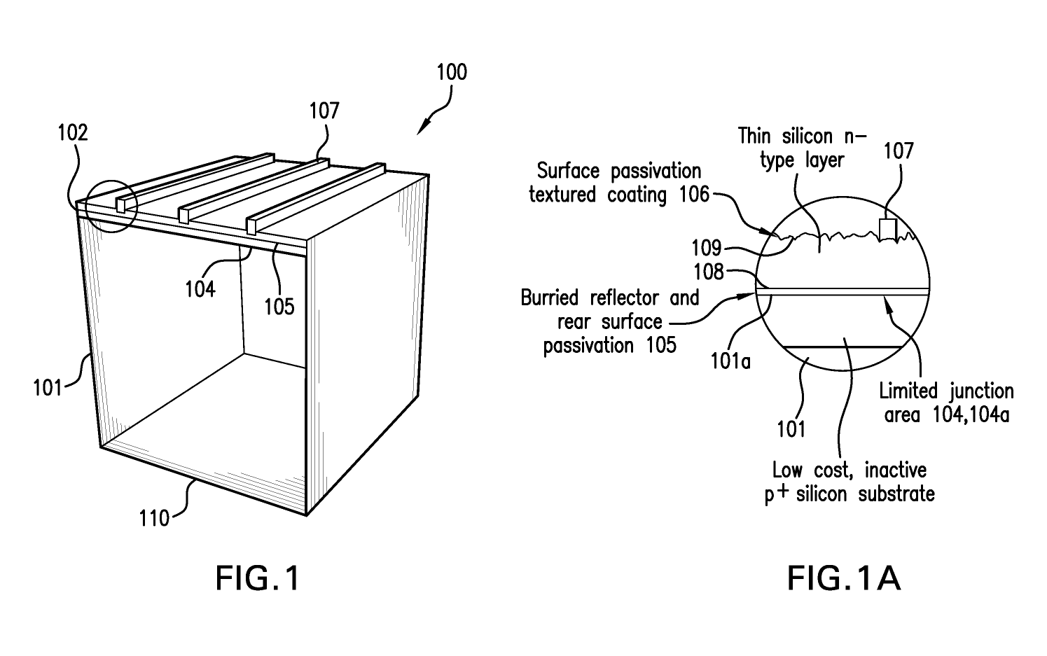

Referring to FIGS. 1 and 1a, a photovoltaic device 100 having a front and back orientation is shown schematically. The device 100 comprises a crystalline substrate 101 having a resistivity, such as greater than about 0.02 ohm-cm. Over the substrate 101 is an epitaxy, thin-film layer 102. The thin-film layer 102 contacts the substrate in at least one region 104 to define a p-n junction 104a. To harness the electrical energy generated by the PV cell, front ohmic contacts 107 are electrically connected to the front of the cell 100, while a back ohmic contact 110 is electrically connected to the back. These elements are further considered in detail below.

The substrate 101 has several important functions. First, it provides physical support for the thin-film layer 102. It may be the sole support for the thin-film layer or it may be used in combination with another substrate such a metal or ceramic layer to provide additionally rigidity. The substrate also forms the p-n junction 104a with the thin-film layer. The substrate of the present invention, however, also provides fault tolerance. As mentioned above, this fault tolerance facilitates the use of a thin-film epitaxy layer.

Fault tolerance is achieved by using a semiconductor with a certain resistivity, such as greater than 0.02 ohm-cm. For example, it has been found that satisfactory fault tolerance is achieved when the resistivity of the substrate is greater than about 0.02 ohm-cm. Preferably, the resistivity is greater than about 0.04 ohm-cm, and, more preferably, greater than about 0.1 ohm-cm.

Although greater resistivity tends to improve fault tolerance, at some point, the resistivity begins to impede the carrier flow through the p-n junction to the point that the voltage across the cell drops excessively. Thus, establishing the desired degree of resistivity in the substrate becomes an optimization of voltage across the cell versus fault tolerance. Fortunately, this is a wide window, meaning that the resistivity can be increased significantly without a corresponding drop in voltage. It has been found that suitable voltages are provided up to a resistivity of about 1 ohm-cm, although meaningful voltage drops begins at about 0.2 ohm-cm.

Therefore, in light of the discussion above, the resistivity of the substrate is preferably an optimization of fault tolerance and voltage drop among other factors. Accordingly, applicants have found a substrate having a resistivity of about 0.02 to about 1 ohm-cm is suitable, about 0.02 to about 0.5 ohm-cm is preferred, about 0.05 to about 0.2 ohm-cm is more preferred, and about 0.1 to about 0.2 ohm-cm is even more preferred.

It should be understood, however, that the resistivity of the substrate might be modified for particular applications. For example, if the thin-film layer is of a higher quality, it may be satisfactory for the substrate to have a slightly lower resistivity (and less fault tolerance) in favor of a higher voltage. Alternatively, if the thin layer is problematic (defect prone), then it may be worthwhile to increase the resistivity of the substrate to increase fault tolerance.

The substrate may be doped to be a p or an n-type substrate. Preferably, the substrate is doped or refined to be a p substrate for a number of reasons. For example, there are certain advantages to having an n-type thin film as discussed below. A p-type substrate with a n-type epitaxial layer can provide a more efficient PV device, such as on the order of 15% (relative) more efficient.

Suitable semiconductor materials for the substrate include, for example, silicon, or a mixture of silicon and another semiconductor material with a higher melting point than silicon, such as silicon carbide (SiC). Alternate substrates include metallurgical-grade silicon, or a thin silicon layer on steel, which provides enhanced flexibility and electrical contact conduction.

Preferably, the semiconductor is silicon, which may be monocrystalline or multi-crystalline. Preferably, the material is multi-crystalline since such a structure can be produced in high volume using conventional casting techniques. The substrate also does not need to be of high purity. For example, device-grade silicon typically requires a purity of 6N (i.e., 99.9999%), while the purity demands for the substrate in the present invention application are much less, for example, from below 6N to 3N. Preferably, the purity is 4N, which is less than that required in most semiconductor applications.

Suitable p-type dopants are well known and include for example, boron, aluminum, gallium and indium. Generally, boron is preferred since it is naturally occurring in silicon, the preferred substrate material. The desired levels of doping can thus be achieved simply by not purifying the semiconductor to traditional levels. For example, suitable results have been achieved by using a multi-crystalline silicon doped with about 1-20 ppmw boron. Preferably, the semiconductor is doped with about 5-15 ppmw boron, and even more preferably, the semiconductor is doped to about 7-10 ppmw.

In a preferred embodiment, the substrate is a 4N or purer multi-crystalline silicon having a resistivity of about 0.1 ohm-cm to about 0.2 ohm-cm. Such a material is preferred from the standpoint of performance, availability and cost.

The substrate should be thick enough to provide the desired stability and fault protection. Although the thickness of the substrate varies according to the application, suitable results have been achieved using a substrate of about 200 to about 700 μm.

As mentioned above, the substrate's fault tolerance facilitates the use of an epitaxial, thin-film layer 102. As used herein, the term “thin-film layer” refers to a layer of semiconductor material that can be deposited using known chemical and physical deposition techniques, such as to a thickness no greater than about 50 μm. As is well known, epitaxial growth describes an ordered crystalline growth on a crystalline substrate. Epitaxial films may be grown from gaseous or liquid precursors. Because the substrate acts as a seed crystal, the deposited film takes on a lattice structure and orientation identical to those of the substrate. The surface of the epitaxial thin film layer (e.g., Si thin film layer) mimics the surface morphology of the substrate or surface where the thin layer is grown on.

Epitaxially-grown, thin-film layers have a number of advantages over bulk silicon. First, they are very efficient due to the close proximity of the charge carriers to the p-n junction. Additionally, thin-films use less material and typically require less time to form. Although thinner films tend to be more susceptible to defects such as voids, holes, crystalline boundaries, faults and manufacturing variances in thickness and consistency, these problems are mitigated by the fault tolerant substrate. As an option, the semiconductor thin film layer can comprise a heavily doped interface layer (interface to the substrate or other layer adjacent to the substrate) and a lighter doped absorber layer, which is closer to the surface of the device (or further away from the substrate). The doping is a reference to the doping used to form the n-type or p-type thin film layer. As an example, the interface layer can be doped 10% to 100% by weight more in ppmw than the absorber layer, such as from 40% to 70% by weight.

Traditional epitaxial growth techniques can be used including chemical vapor deposition or liquid deposition. Chemical vapor deposition (CVD) is a chemical process used to produce high-purity, high-performance solid materials. In a typical CVD process, the wafer (substrate) is exposed to one or more volatile precursors, which react and/or decompose on the substrate surface to produce the desired deposit. Frequently, volatile byproducts are also produced, which are removed by gas flow through the reaction chamber. Below is an example of the various CVD techniques that can be used:
Atmospheric pressure CVD (APCVD)—CVD processes at atmospheric pressure.
Low-pressure CVD (LPCVD)—CVD processes at subatmospheric pressures. Reduced pressures tend to reduce unwanted gas-phase reactions and improve film uniformity across the wafer.
Ultrahigh vacuum CVD (UHVCVD)—CVD processes at a very low pressure, typically below 10⁻⁶ Pa (˜10-8 torr).
Aerosol assisted CVD (AACVD)—A CVD process in which the precursors are transported to the substrate by means of a liquid/gas aerosol, which can be generated ultrasonically.
Direct liquid injection CVD (DLICVD)—A CVD process in which the precursors are in liquid form (liquid or solid dissolved in a convenient solvent). Liquid solutions are injected in a vaporization chamber, vaporized, and transported to the substrate as in classical CVD process. This technique is suitable for use on liquid or solid precursors. High growth rates can be reached using this technique.
Plasma methods
Microwave plasma-assisted CVD (MPCVD)
Plasma-Enhanced CVD (PECVD)—CVD processes that utilize a plasma to enhance chemical reaction rates of the precursors. PECVD processing allows deposition at lower temperatures.
Remote plasma-enhanced CVD (RPECVD)—Similar to PECVD except that the wafer substrate is not directly in the plasma discharge region. Removing a the wafer from the plasma region allows processing temperatures down to room temperature.
Atomic layer CVD (ALCVD)—Deposits successive layers of different substances to produce layered, crystalline films.
Hot wire CVD (HWCVD) (also known as Catalytic CVD (Cat-CVD) or hot filament CVD (HFCVD))—Uses a hot filament to chemically decompose the source gases.
Metalorganic chemical vapor deposition (MOCVD)—CVD processes based on metalorganic precursors.
Rapid thermal CVD (RTCVD)—CVD processes that use heating lamps or other methods to rapidly heat the wafer substrate. Heating only the substrate rather than the gas or chamber walls helps reduce unwanted gas phase reactions that can lead to particle formation.
Vapor phase epitaxy (VPE)—generally any process that is not LPE or growth from molten silicon.

In addition to CVD, the thin-film layer may be grown by liquid phase epitaxy (LPE), which is a method to grow semiconductor crystal layers from a melt on solid substrates. This happens at temperatures well below the melting point of the deposited semiconductor. The semiconductor is dissolved in the melt of another material. At conditions that are close to the equilibrium between dissolution and deposition, the deposition of the semiconductor crystal on the substrate is slow and uniform. The growth of the layer from the liquid phase can be controlled by a forced cooling of the melt.

Another class of growth is growth from molten silicon by depositing a layer of silicon, melting it, and then growing silicon crystals—either epitaxially or on a dissimilar substrate. The initial silicon layer can be deposited by CVD, spraying, dipping, screen printing, etc. This layer is then heated to its melting point (possibly using an optical furnace which can focus the heat on the top layer). The crystals are grown when the molten silicon is cooled. It should be recognized that this method is hard to control on a silicon based substrate since the substrate and interfaces will also tend to melt. In forming the PV device of the present invention, a fire-thru metallization process can be used. This can involve subjecting the PV device that includes the front contacts and subjecting the PV device to high temperatures, like 700 to 900 deg C. for several seconds to several minutes, like 5 seconds to 5 minutes. As an option, hydrogenation can be used on the PV device. The hydrogenation can improve the Fill Factor. Hydrogenation can involve or include hydrogen annealing or an atomic hydrogen plasma treatment.

In one embodiment, the thin-film layer 102 is grown over other planar elements on the substrate 101, such as an optical reflector 108. This requires that the thin film be grown laterally from the seed area (i.e., the p-n junction) to cover the reflector or barrier. This is defined as local epitaxial growth, which initially occurs in the direction normal to the surface of the silicon substrate, but then proceeds preferentially in the direction parallel to the surface of the substrate. Vertical growth starts from the single-crystal seed area, but lateral growth may continue over non-crystalline silicon oxide coated portion of the substrate

This lateral growth, which is also referred to as epitaxial lateral overgrowth (ELO), may be performed as discussed in G. W. Neudeck et al., Three Dimensional Devices Fabricated by Silicon Epitaxial Lateral Overgrowth, JOURNAL OF ELECTRONIC MATERIALS, Col. 19, No. 10, 1990 (incorporated herein by reference). This method provides an active layer with high mobilities, large minority carrier lifetimes, and does not damage underlying active substrate. Although this technology suggests processing temperatures below 1000° C., applicants have found that slighter higher processing temperatures (e.g., about 1150° C.) provide for better results.

ELO can involve “seed” windows (i.e., p-n junctions 104a), which are opened on the substrate 101. Epitaxial growth is initiated selectively in the seed windows or vias, and progresses vertically until the level of the reflector 105 or barrier 108 is reached. Continuing to grow, the epitaxy will go laterally over the planar element producing a single crystalline silicon layer available further device processing.

The process generally involves growing thermal SiO₂ layer on a mirror polished <100> or <111> single or multi-crystalline silicon wafer (the substrate). Portions of the SiO₂ layer are then removed to produce the vias. To this end, the wafer is photolithographically patterned using a photoresist. The exposed oxide pattern is removed using diluted HF acid or other suitable acid, thereby forming the silicon vias in the remaining SiO₂. The remaining photoresist is then removed which exposes the SiO₂ layer. Epitaxial silicon is then deposited on substrate and SiO2 layer patterned with Si vias.

Applicants have found that the spacing and orientation of the vias can be helpful in achieving desirable lateral growth. Specifically, epitaxial silicon appears to prefer lateral overgrowth when the exposed silicon via patterns are oriented 45 degrees off the direction of the gas flow and cleave plane. (This statement applies to both <100> and <111> crystal structures). Patterns with the silicon vias oriented either perpendicular or parallel to the gas flow have less overgrowth and more defected epitaxial layers. Furthermore, vias patterned perpendicular to the gas flow appear to have sharp pyramid-like points.

The epitaxial silicon can join between the vias. Applicants have found that, for the silicon to join between vias, the epi thickness can be approximately half (or more) of the distance between vias. For example, a via spacing of 10 μm can involve a vertical growth of about 5 μm.

Suitable semiconductor materials for the thin-film include, for example, silicon, III-V compounds and II-VI compounds. Preferably, the thin-film material is silicon. Since the layer is thin, 5N purity is acceptable, although 6N or greater is desirable.

The thin-film layer can be doped type p or type n depending on application. Suitable dopants include, for example, boron for p-type and phosphorus for n-type.

As mentioned above, preferably, the substrate is p-type and the thin film is n-type. Among the other reasons for this preference already mentioned, it has been found that an n-type thin film is generally easier to passivate (which lowers the surface recombination potential and leads to higher efficiency). In this regard, in certain applications it may be preferable to passivate the top of the thin-film layer to form a passivated surface 106. This is a well known technique described in detail below. The semiconductor thin film surface can be passivated such as by diffusing phosphorus or other passivating agents. This passivation can reduce the lateral resistance of the device.

Thickness of the thin-film layer can vary according to the application. Generally, it is preferred to make the layer thin to reduce the distance from the p-n junction, thereby eliminating the opportunity for the charge carriers to recombine. If the layer is too thin, however, the inevitable defects characteristic of a lower-tier, CVD, epitaxy layer become a more substantial component of the overall mass, thus leading to more ground faults. Suitable results have been achieved using a thin-film layer of about 5 to about 50 μm. Preferably, the thickness of the thin-film layer is about 5 μm to about 25 μm, and more preferably from about 5 μm to about 10 μm.

To enhance performance of the cell, it may be preferable to use light-capturing optics, such as reflectors 105 and/or a textured surface 109, to convert more photons to charge carriers, and isolating barriers 108 to limit the size of the p-n junctions 104a to increase the voltage across the cell (see FIG. 1a).

Light-capturing optics are discussed in Duerinckx et al., Optical Path Length Enhancement for >13% Screenprinted Thin Film Silicon Solar Cells, Presented at the 21st European Photovoltaic Solar Energy Conference, Dresden, Germany, Sep. 4-7, 2006, which is herein incorporated by reference. It is preferred to texture the front surface 109, not only to decrease the front surface reflection, but also to increase the optical path length in the thin-film layer by scattering the light at an oblique angle. Front surface texture can be random pyramidal, and can be formed using a wet chemical etch solution consisting of NaOH/KOH, H2O, and isopropyl alcohol. Front surface texture may also be random pitted, and can be formed by using a dry plasma consisting of CF4 and O2 or SF6 and O2. Ideally, the surface should be a lambertian refractor. In practice, it has been found that complete light scattering can be achieved for a Si removal of only 1.75 μm. However, since the epitaxial layer is quite thin, the silicon removal during the texturing step should be carefully controlled. If only a very limited amount of silicon is removed (short texturing) then the specular reflective component increases at higher wavelengths thereby limiting the diffusive behavior. A longer texturing rectifies this problem at the cost of more silicon being removed. Consequently, a compromise must be made between light scattering and the absorption volume of the epitaxial layer. A good uniform texturing is achieved with a limited removal of about 0.5 to about 1.0 μm, even though a lambertian surface texture (100% diffusive) is not quite achieved. Fluorine based plasma texturing has been found to achieve these objectives.

The device can employ one or more reflectors to decrease the transmittance of long wavelength light into the substrate. Specifically, by positioning a reflector at the epi/substrate interface, photons that reach this interface are reflected and pass a second time through the thin-film layer. Since the light is preferably diffuse from the moment it entered the cell (due to the lambertian nature of the plasma texture mentioned above), a large part of photons will strike the front surface outside the escape angle. Therefore, most the photons will be reflected back down toward the substrate due to Total Internal Reflectance (TIR). The photons continue to reflect between the reflector and the textured surface so that multiple passes through the epitaxial layer become possible.

The reflector can be made by electrochemical growth of a porous silicon stack of alternating high and low porosity layers (a multiple Bragg reflector). This process is described in detail in Duerinckx et al. During the epitaxial growth on top of the porous Si stack, the individual layers reorganize into Quasi Monocrystalline Silicon (QMS). The nanoporous layers are transformed into thin silicon layers with large voids, although the original layout of the stack is maintained. According to Duerinckx et al., this process is driven by minimization of surface energy. The result is alternating layers of small and large voids. This structure tends to be suitable as a reflector due to constructive interference.

As mentioned above, the voltage across the PV cell can be increased by decreasing the size of the p-n junction relative to the area of the photon-collecting, thin-film layer 102. To this end, insulating barriers 108 are disposed on the substrate to define first regions 104 in which the thin-film layer contacts the substrate (i.e., the p-n junctions) and second regions in which the thin-film layer is isolated from the substrate. Preferably, the barriers cover a majority of said substrate to define p-n junctions over a minority portion of said substrate. In a preferred embodiment, the second regions comprise at least about 80% of the substrate surface area, and, more preferably about 95 to about 99%.

Although not necessary, it is usually preferable to deposit the barriers in a periodic fashion to produce a pattern of p-n junctions/first regions. For example, as shown in FIG. 1, the first regions are defined as parallel rows. Alternatively, the second region may encompass a first region, to define the first regions as discrete shapes (e.g., round or polygonal). In any event, preferably, the distance between centers of any two adjacent first regions is less than a minority carrier diffusion length in the thin-film layer. For example, in an n-type thin film this length would be from about 10 μm to about 100 μm. Thus, in a preferred embodiment, the centers of the first region are no greater than about 5 μm to about 50 μm apart.

As an option, a thin (e.g., 0.01 to 1.0 microns) p-layer may be grown over the barrier to overcome the diffusion length limitations. This p-layer converts the generated minority carriers to majority carriers, which then are readily transported to the p-n junctions. As an option, rather than growing a p-type layer over the barrier, an n-type layer may be grown over the p-type barrier such that the p-type dopant in the barrier diffuses into the initial n-type layer to render it a p-type layer. In one embodiment, this initial n-type layer is grown separately from the thin-film layer, and, in another embodiment, it is the thin-film layer.

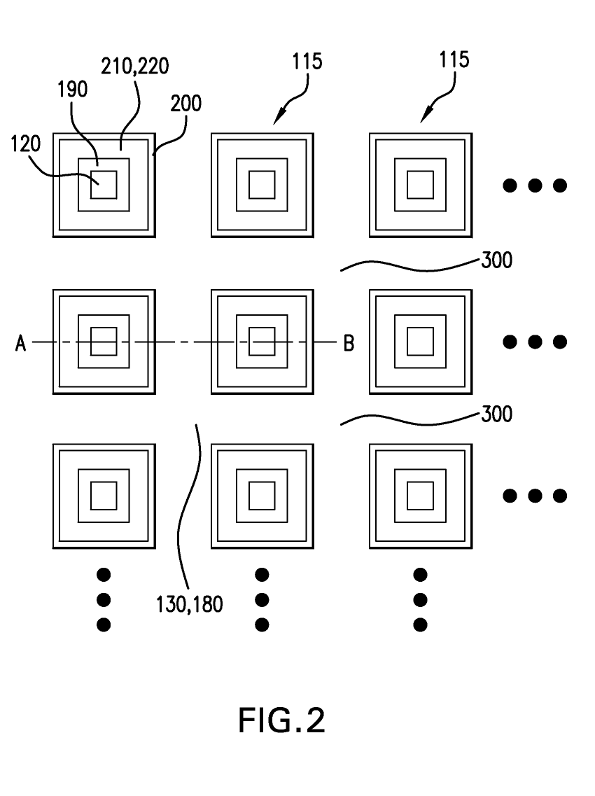

Referring to FIGS. 2-4, a particular embodiment of the PV cell and steps for manufacturing it are considered in detail. It should be understood that this particular embodiment is for illustrative purposes only, and that other embodiments may be practiced within the scope of the claims.

FIG. 2 shows a plan view of a first embodiment of a front-surface-illuminated photovoltaic device. An array of first regions 115 is laterally intermixed with second regions 300 where, in this embodiment, second regions 300 are the space between first regions 115. The first regions 115 have the shape of a square. Alternatively, first regions 115 could have the shape of any closed, bounded regions, such as polygons or circles, or they could be stripes extending laterally across the device. First regions 115 could also have varied shapes over the device, such as a mixture of bounded regions and stripes. In this embodiment, the first regions 115 (and concurrently second regions 300) are defined by holes formed through multiple layers, as explained in more detail below. FIG. 2 shows a corner of the device; first regions 115 extend in two dimensions laterally over the device, as indicated by the triplets of dots.

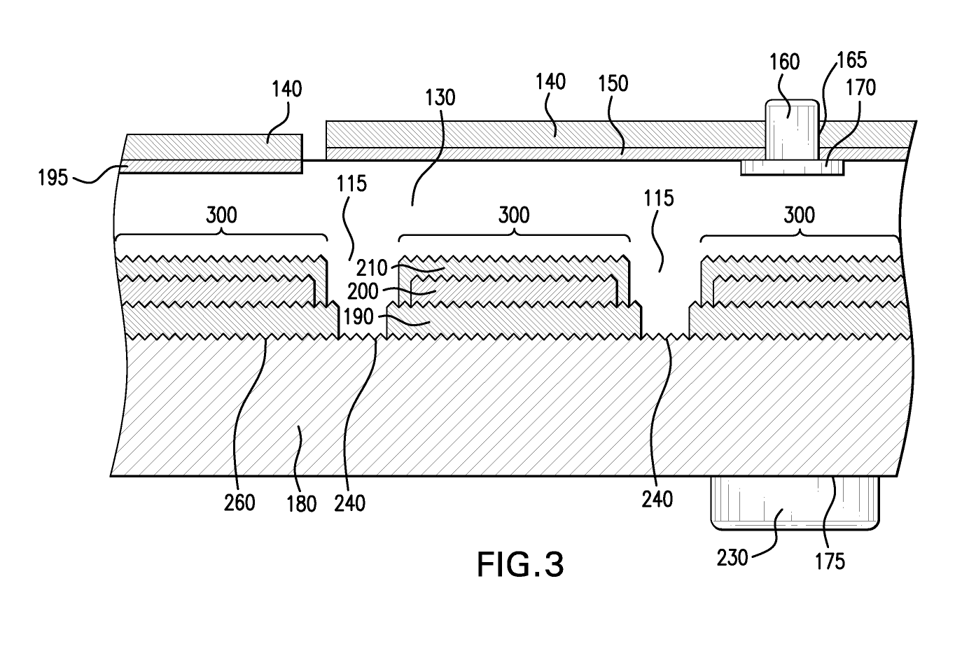

FIG. 3 shows a cross section of the structure of a first embodiment of a front-surface-illuminated photovoltaic device. The cross section is taken along the line A-B in FIG. 2. The device structure contains the following elements: a substrate 180 with a back surface; a thin-film layer 130, of doping type opposite to that of substrate 180 and having a front surface; a barrier layer 190 in contact with the substrate 180; a reflector layer 200 in contact with the barrier layer 190; at least one front-surface ohmic contact 160 (through opening(s) 165) for electrical contact to the thin-film layer 130; and at least one back surface ohmic contact 230 for electrical contact to the substrate 180.

Still referring to FIG. 3, the first regions 115 contain essential p-n junctions 240 for operation of the photovoltaic device. The p-n junctions 240 may be formed at the junction between the substrate 180 and the oppositely doped thin-film layer 130. The second regions 300 contain barrier layer 190 and reflector layer 200. Barrier layer 190 acts as a barrier to diffusion of impurities from substrate 180 into the rest of the device. Barrier layer 190 may enable the use of a lower purity (hence less expensive) material for the substrate 180. Barrier layer 190 also restricts carrier flow between the substrate and the thin-film layer. Reflector layer 200 acts to reflect photons entering the front surface back into thin-film layer 130 if those photons penetrate all the way to the reflector layer 200 without being absorbed in the thin-film layer 130. The presence of reflector layer 200 may therefore increase the efficiency of the device by making it more likely that a photon will be absorbed in thin-film layer 130, thus producing more electron-hole pairs that can be collected and contribute to the generated current.

As an option, as shown in the embodiment in FIG. 3, there may be an internal passivation layer 210 at least partially encapsulating reflector layer 200 in second regions 300. Internal passivation layer 210 is meant to prevent diffusion of the material of reflector layer 200 into the rest of the device. In the embodiment shown in FIG. 3, passivation layer 210 and barrier layer 190 completely encapsulate reflector layer 200, with passivation layer 210 wrapping around the edges of reflector layer 200. Alternatively, passivation layer 210 may at least partially encapsulate barrier layer 190 by extending over the edges of barrier layer 190. Alternatively, if the material of reflector layer 200 is unlikely to diffuse significantly into the rest of the device during the processing of the device, internal passivation layer 210 may be omitted.

The device may have front passivation on the front surface to reduce recombination over the front surface and, in general, stabilize the electrical characteristics of the device. The front passivation may be made of at least one of the following: a front passivation layer 150, a floating p-n junction 195, or a heteroface. It could be formed, for example, by deposition of n-type GaP on the top surface of a p-type silicon thin-film layer 130. Floating junction 100 may be formed by diffusion of dopant into thin-film layer 130, the dopant of opposite type to that of thin-film layer 130.

The device may have an anti-reflection coating 140 covering front passivation layer 150 and floating junctions 195. Anti-reflection coating 140 decreases the fraction of incident light reflected from the front surface and therefore improves overall conversion efficiency of the device.

Electrical contact is made to the device using at least one front ohmic contact 160 to thin-film layer 130 and at least one back ohmic contact 230 to substrate 180. Front ohmic contact 160 grid lines can be present and may have a width ranging from 20 microns to 200 microns. Front ohmic contact metallization 160 may be, but are not required to be, fired-through the anti-reflection coating 140. Front ohmic contact 140 can be annealed in H2 or H plasma at a temperature ranging from 300-600 Celsius for a duration ranging from 30 seconds to 30 minutes. Front electrical contact can be aided by adding a high concentration of dopant, which simultaneously acts as the front passivation layer 150, into the top surface which results in an electrical sheet resistance ranging from 30 to 300 ohm per square. An additional doping layer (not shown) may be added to substrate 180 at back contact interface 175 to decrease contact resistance. Alternatively, separate doping for the back contact 230 may not be required; the doping of the substrate 180 may be sufficiently high to give an ohmic contact without additional doping at interface 175. In one embodiment, the doping of the substrate can be as high as it needs to be to get good ohmic contact with the deposited back contact metal 230. There would not be a need for a diffused or alloyed layer at the interface 175. For the front ohmic contact 160, additional doping layer 170 may be formed in thin-film layer 130 to reduce recombination at the front contact. For example, if the thin-film layer 130 is n-type, an n+ layer may be fabricated under the contacts. Front passivation layer 150, a heteroface, or a floating junction 195 reduces recombination across the rest of the front surface.

The front contact 160 may be buried. In an embodiment in which internal passivation layer 210 is not present, and reflector layer 200 is a good electrical conductor, such as a metal, an electrical connection may be established from front metal contact 160 to reflector layer 200 by using a heavily doped vertical layer (not shown).

Barrier layer 190, reflector layer 200, and internal passivation layer 210 add front to a total thickness between about 0.1 and about 0.5 micrometers. Barrier layer 190 material may be a nitride of silicon, an oxide of silicon, an oxide of aluminum, aluminum nitride, tungsten carbide, titanium carbide, or silicon carbide. Reflector layer 200 should have high reflectivity at light wavelengths close to the bandgap absorption wavelengths of the semiconductor material of thin-film layer 130. Reflector layer 200 may be a metal or a non-metal. If thin-film layer 130 is primarily silicon, appropriate metals for reflector layer 200 include nickel, silver, chrome, palladium or any combination thereof. Appropriate non-metals include titanium nitride, boron carbide, silicon carbide, or any combination thereof. Internal passivation layer 210 may be a nitride of silicon, an oxide of silicon, a carbide of silicon, or any combination thereof. Internal passivation layer 210 may also be a wide bandgap material, such as silicon carbide (SiC) which may form a high-low semiconductor junction with seed layer 220 or directly with thin-film layer 130.

Front passivation layer 150 may be made of amorphous silicon, a nitride of silicon, or an oxide of silicon, or a combination of these.

Anti-reflection coating 140 may have a single layer or multiple layers of materials which are at least partially transparent to light in the range of wavelengths from the infra-red through the ultraviolet and which have appropriate indices of refraction and thicknesses. Suitable materials include, but are not limited to, a nitride of silicon, an oxide of titanium, an oxide of tantalum, an oxide of aluminum, an oxide of silicon, magnesium fluoride, zinc sulfide, sodium hexafluoroaluminate, or any combination thereof. Anti-reflection coating 140 thickness can range from 400 to 2500 Angstroms with an index of refraction ranging from 1.3 to 2.4.

The thickness of thin-film layer 130 in this embodiment is between about 2 and about 50 micrometers.

In operation, photons enter the device through the front surface. Photons may be absorbed directly in thin-film layer 130. Some photons, especially those of longer wavelength, may pass completely through thin-film layer 130 to reflector layer 200 without being absorbed. They may then be reflected back into thin-film layer 130 and absorbed. If substrate 180 has a textured surface 260, reflector layer 200 may also have a textured surface, and photons striking reflector layer 200 will be scattered as well as reflected, increasing the optical path length and the likelihood of absorption in thin-film layer 130. Photons may also pass through to textured surface 260 of substrate 180 in the first regions 115 where they are scattered back into thin-film layer 130 and then absorbed. Once a photon is absorbed, an electron-hole pair is formed and the two carriers thermally diffuse. Carriers reaching depletion regions of p-n junctions 240 will be swept out, or collected, by the built-in electric fields of junctions 240 and contribute to external photocurrent.

For good efficiency of carrier collection, distances between openings defining first regions 115 should be small enough that carriers are collected before they recombine. One way this may be achieved is to make lateral distance between centers of any two adjacent first regions 115 less than one minority carrier diffusion length in thin-film layer 130. In general, the distance between openings defining first regions 115 and/or the sizes of the openings may be chosen to optimize efficiency for a given diffusion length (or carrier lifetime) in thin-film layer 130. For a silicon device, it is expected that the distance between centers of first regions 115 will fall in the range from about 2 to about 1000 micrometers, and the width of first regions 115 is expected to fall in the range from about 1 to about 50 micrometers.

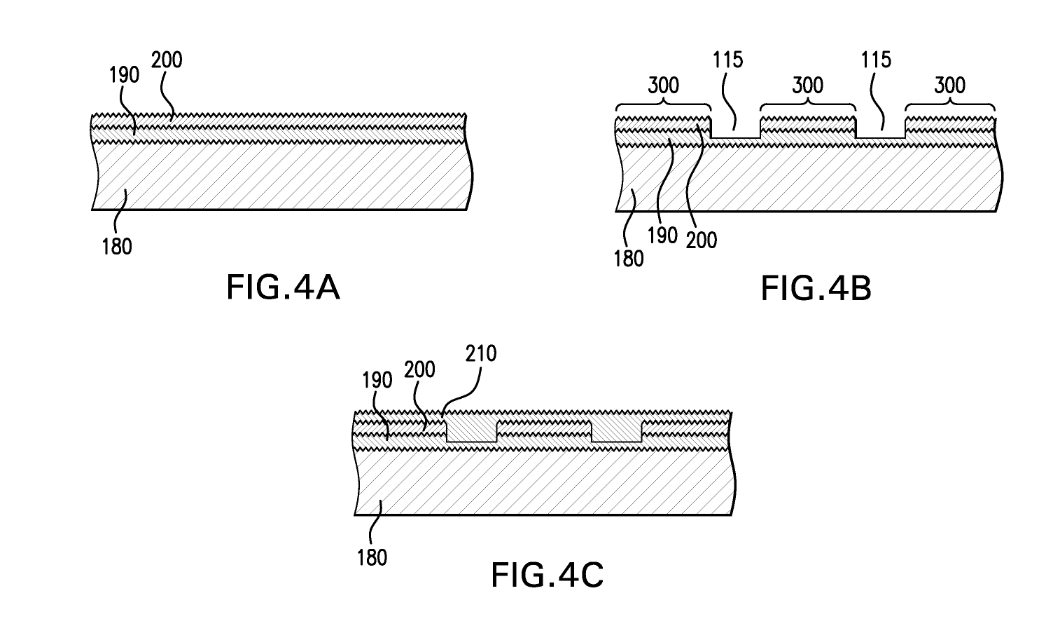

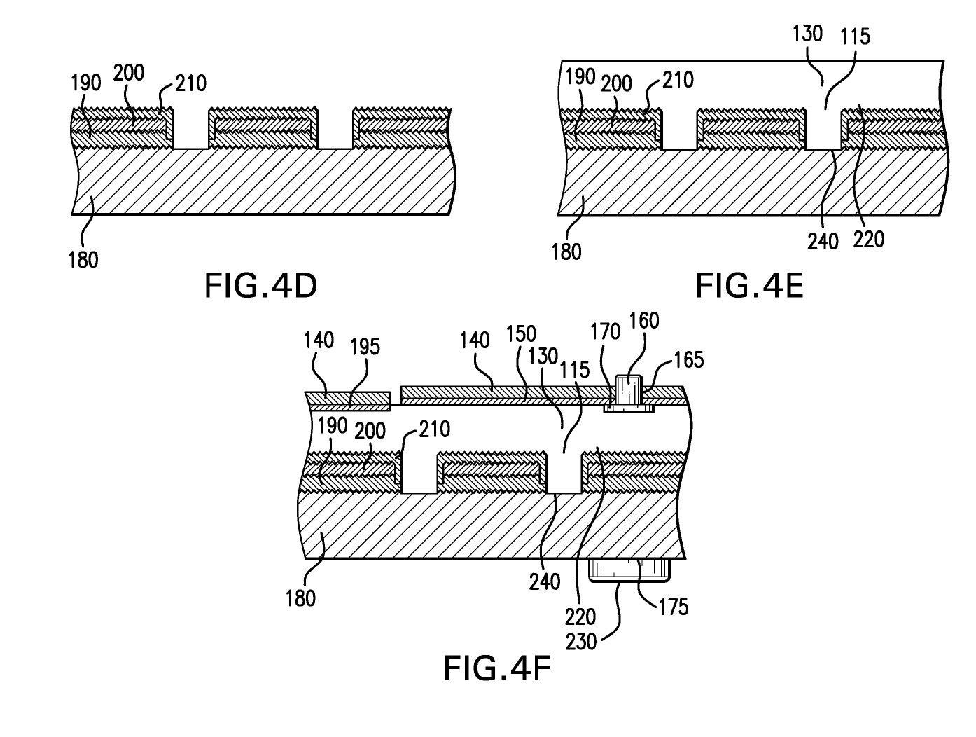

FIGS. 4A-F show an embodiment of a process for fabricating the embodiment of a solar photovoltaic device shown in FIGS. 2 and 3. FIG. 4A shows the device structure after the steps of obtaining a semiconductor substrate 180 of a first doping type with a top and bottom surface; forming barrier layer 190 on the top surface; and depositing reflector layer 200 on barrier layer 190. Prior to the forming of barrier layer 190, substrate 180 may be textured to enhance light scattering from the top surface of substrate 180 back into thin-film layer 130, as disclosed above. The texturing can be achieved by texturing a mold in which substrate 180 is cast. Alternatively, texturing may be achieved by forming a mixture of the semiconductor material of substrate 180 and particles of a thin-film having a melting point higher than that of the material of substrate 180; heating the mixture to a temperature above the melting point of the substrate and below the melting temperature of the thin-film, and cooling the mixture below the melting point of the substrate. The particles impart texture to substrate 180. As a specific example, substrate 180 is silicon and silicon carbide (SiC), and the proportion of silicon carbide, by volume, is in the range from about 1% to about 90%. The particles may have sizes in the range from about 0.1 to about 1.0 micrometers. The texturing is configured to scatter light in the wavelength range from the infrared to the ultraviolet.

Barrier layer 190 and reflector layer 200 may be formed using any known deposition technique including, but not limited to, APCVD, LPCVD, PECVD, MOCVD, or other chemical vapor deposition methods; evaporation; sputtering; spray pyrolysis; or printing. Barrier layer 190 may be formed using thermal oxidation.

FIG. 4B shows the structure after a step of forming a plurality of openings through reflector layer 200 and barrier layer 190. The openings define a plurality of first regions 115 and the spaces separating the openings define second regions 300. The openings may be formed using known techniques including, but not limited to, wet chemical etching; dry etching, such as plasma etching; laser machining; air abrading; or water blasting. If the surface of substrate 180 is textured, openings may be formed through thinning layers on surface-textured peaks: the reflector and barrier layers will be thinner over the peaks of the texture than over the valleys, and these thinner regions can be etched away, exposing the underlying substrate 180, while leaving the substrate 180 covered in the thicker regions. Some of these methods, such as wet or dry etching, may require a masking step, such as photolithography using photoresist. Others, such as laser machining, may not require a masking step.

FIG. 4C shows the structure after a step of depositing internal passivation layer 210 covering reflector layer 200. Passivation layer 210 may be deposited using chemical vapor deposition, sputtering, spray pyrolysis, or printing.

FIG. 4D shows the structure after completion of a step of completing the forming of openings defining first regions 115 by forming a plurality of openings in internal passivation layer 210 coinciding with the openings defining the first regions, such that the remaining internal passivation layer 210 at least partially encapsulates the reflector layer 200 at edges of the second regions. A patterned photoresist layer may be used to define the areas to be etched. Alternatively, barrier layer 190 may be partially encapsulated by passivation layer 210 as well. In this step, the top surface of substrate 180 is exposed. Openings in passivation layer 210 may be formed using any of the techniques disclosed above in connection with FIG. 4B.

FIG. 4E shows the structure after a step of depositing semiconductor thin-film layer 130 covering first regions 115 and second regions 300 and forming p-n junctions 240 inside the openings defining first regions 115.

As discussed above, epitaxially depositing the semiconductor layer may be carried out using liquid or chemical vapor deposition (CVD), preferably CVD. As one example, trichlorosilane may be used in the CVD step to deposit silicon thin-film layer 130. Prior to CVD deposition, substrate 180 may be cleaned using known techniques, such as an etch with HCl. This step could be done in-situ in a CVD reactor. Thin-film layer 130 may have acceptable electronic properties as deposited. As mentioned above, the thin-film layer is preferably grown epitaxially over the reflector 200 (and passivation layer 210).

FIG. 4F shows the structure after the steps of forming one or more ohmic contacts to thin-film layer 130 and to substrate 180; also front passivation layer 150, floating junction 195, and anti-reflection coating 140. Ohmic contact to thin-film layer 130 contains metal 160 and additional doping layer 170 in thin-film layer 130 to reduce recombination. Doping layer 170 may be formed by diffusion, ion implantation, or other known techniques. Ohmic contact to substrate contains metal 230 in contact with substrate 180 at back contact interface 175. Optionally, additional doping may be introduced at interface 175, similar to layer 170. Ohmic contacts to thin-film layer 130 may be formed by depositing passivation layer 150 and anti-reflection coating 140, then forming openings 165 through both of these layers. Metal 160 is deposited and patterned using known techniques. Alternatively, forming ohmic contacts to thin-film layer 130 may include screen printing metal 160, such as silver, on front passivation layer 150 and firing the metal through passivation layer 150. Alternatively, metal 160 may be fired through anti-reflection coating 140 if metal 160 is applied before contact openings 165 are formed.

Front passivation layer 150 may be deposited using any of the deposition techniques disclosed above in the description of FIG. 4A. Front passivation layer 150 may form a hetero-junction (an electrical junction between dissimilar semiconductor materials) with thin-film layer 130.

Before deposition of passivation layer 150, the front surface of thin-film layer 130 may be textured, either mechanically, chemically, or with a combination of these methods, to reduce front surface reflectance.

In an alternative embodiment, the device has substrate 180, thin-film layer 130 of opposite doping type to the substrate 180 and deposited on substrate 180, at least one ohmic contact 160 to the thin-film layer, and at least one ohmic contact 230 to substrate 180. As in previously described embodiments, this embodiment may also have front passivation, single- or multiple-layer a reflection coating, and textured surfaces on the substrate and thin-film layers. Materials for these structures and methods for making this device may be as previously disclosed.

As an option, due to the ability of the PV device's ability to work with impurities in the substrate and defects in the thin film as described herein, the PV devices or components thereof can be formed in a non-clean room environment as that term is understood in the semiconductor industry. The ability to form a PV device (and achieve the one or more properties as stated herein) as described herein in a factory setting, without the need to have a clean room set-up, provides cost savings, ease of production, and other advantages.

The PV device of the present invention can be as simple as a substrate as described herein with a thin film semiconductor layer located thereon and forming a p-n junction. One or more of the additional options can be present, such as a barrier layer located between the substrate and thin film layer, a reflector layer located between the substrate and thin film layer, a passivation layer on the thin film layer, a textured surface on the substrate surface that forms the p-n junction with the thin film layer (wherein the thin film layer can be textured), an anti-reflection layer located above the thin film layer, and/or contacts can be present.

Although the invention is illustrated and described herein with reference to specific embodiments, the invention is not intended to be limited to the details shown. Rather, various modifications may be made in the details within the scope and range of equivalents of the claims and without departing from the invention. The properties measured in the examples used the same test standards mentioned above, unless stated otherwise.

### EXAMPLE 1

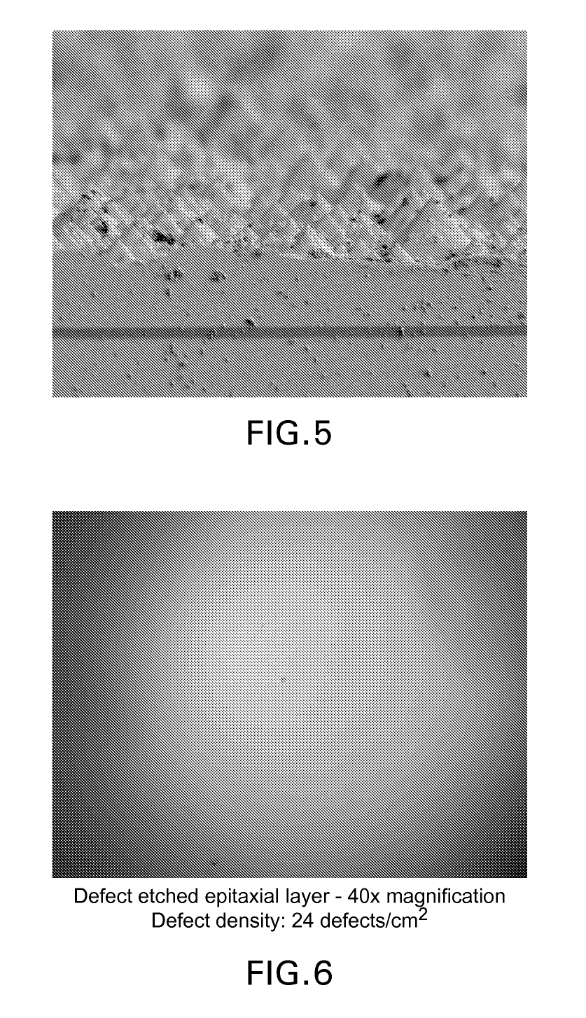

This example demonstrates two thin film photovoltaic devices, one fabricated on a low-resistivity semiconductor-grade mono-crystalline silicon substrate (similar to the device seen in FIG. 5) and the other fabricated on a low resistivity and low cost Upgraded Metallurgical Grade (UMG) mono-crystalline silicon substrate (similar to device seen in FIG. 5). The device has an N-type epitaxial silicon layer with a front surface pyramidal texture on a P+ type mono-crystalline silicon substrate. The thin film epitaxial Si layers on both devices were of high quality, i.e. low defect density. FIG. 6 shows a defect density of a high quality epitaxial layer (<100 defects per cm²). The debris seen on the surface of the device in FIG. 5 is particles due to exposure to a non-cleanroom environment, not crystallographic defects.

The photovoltaic device on semiconductor grade silicon achieved an energy conversion efficiency of 14.80%, Open Circuit Voltage (Voc) of 0.6124 V, Short Circuit Current Density (Jsc) of 30.794 mA/cm2, and Fill Factor (FF) of 78.47%. The photovoltaic device on UMG silicon achieved an energy conversion efficiency of 14.63%, Voc of 0.6219 V, Jsc of 29.96 mA/cm2, and FF of 78.47%.

The PV devices were made as follows. The semiconductor grade substrate was a polished wafer with a resistivity of 0.2 ohm cm. No substrate preparation was performed before epitaxial deposition. The UMG silicon substrate, with a resistivity of 0.05 ohm cm, was sliced from a monocrystalline ingot followed by a dilute alkaline solution saw damage etch process. To remove residual alkaline material from the surface, a dilute HCl solution was used. This was followed by a 3:1 solution of H₂SO₄ and H₂O₂ to remove organic contamination from the silicon substrate surface. Finally, dilute HF was used to remove the thin native oxide (SiO₂) layer from the surface of the substrate.

A similar thin film of epitaxial silicon was deposited onto each of these two different substrates using an Atmospheric Pressure Chemical Vapor Deposition (APCVD) process with trichlorosilane (TCS) as the silicon containing gas in H₂ diluent gas at 760 Torr and 1150 Degrees Celsius. Low concentration PH₃ dopant gas was used to tune the resistivity of the epitaxial thin film to approximately 1 ohm cm. Thickness of the thin film was measured as 25 microns.

Subsequently, a random pyramid structure was textured on the sample surface by a wet chemical process containing dilute NaOH and isopropyl alcohol in H₂O for the purpose of reducing front surface light reflection. The texturing process removed approximately 5 microns of silicon material. A phosphorus diffusion was then performed on the pyramidal textured samples in a belt diffusion furnace for the purpose of serving as front surface field passivation and reducing lateral and contact resistance. The phosphosilicate glass formed during the diffusion was then removed using a dilute liquid HF solution. A silicon nitride layer with a refraction index of 2.1 at 632 nm wavelength and a thickness of 78 nm was deposited onto the epitaxial layer surface using a plasma-enhanced chemical vapor deposition (PECVD) system to serve as the anti-reflection coating and front surface passivation. Finally, the front silver and back aluminum metal contacts were screen-printed onto the sample followed by a firing process through a belt furnace.

### EXAMPLE 2

This example describes the “fault tolerance” exhibited in thin film epitaxial photovoltaic devices that use a silicon substrate having a resistivity of 0.02 ohm-cm or greater. When defects such as stacking faults, dislocations point defects, or voids form in the thin film epitaxial layer, shunt paths occur that may degrade overall solar cell performance. By using a substrate in the mentioned resistivity range, these micro-shunts have been found to negligibly impact the overall device performance as evidenced in Voc measurements, a key measurement of solar cell performance. On the other hand, the performance of thin film photovoltaic devices using substrates below the stated resistivity range is negatively impacted by these faults and therefore these devices do not exhibit “fault tolerance.”

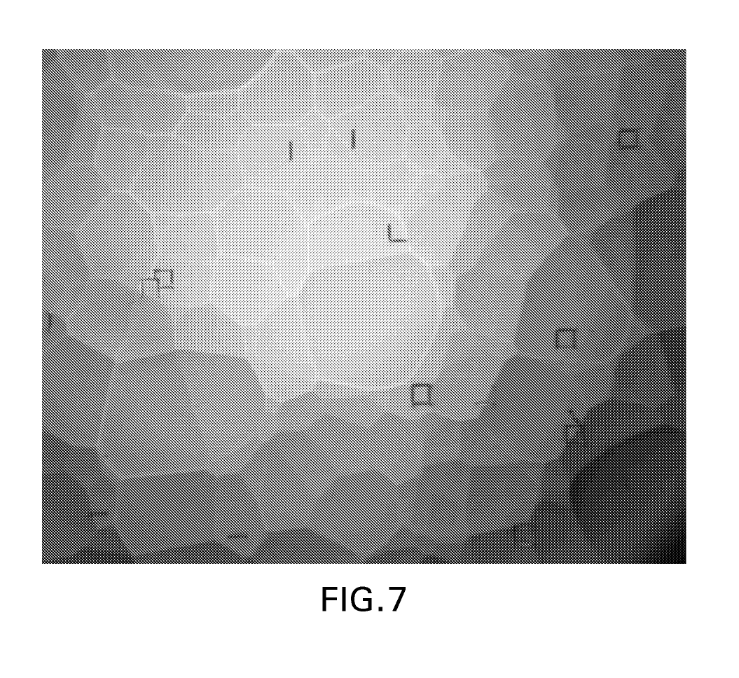

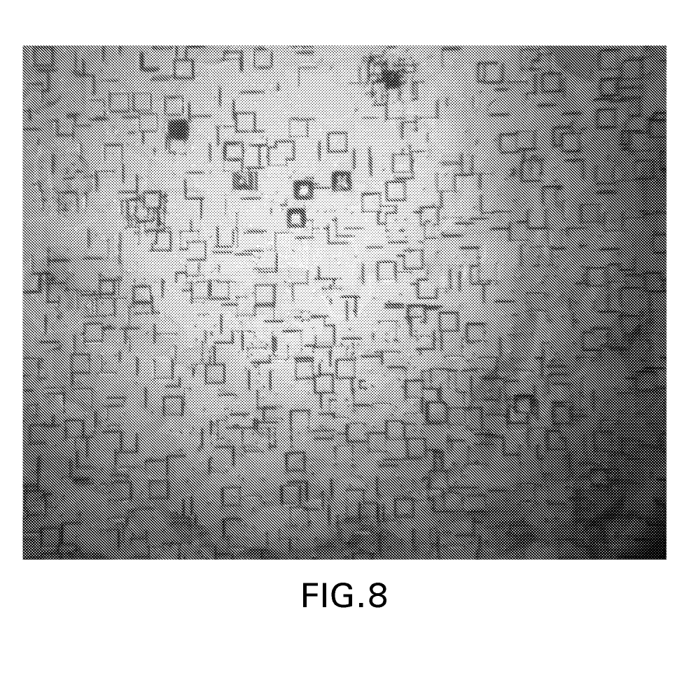

Following Si epitaxial chemical vapor deposition as in Example 1, the front (top) surface was preferentially etched to highlight crystallographic defects present in the N-type thin film layer. Preferential defect etching is done by submerging silicon substrates in a liquid solution of HF, K₂Cr₂O₇, and H₂O for several minutes. This solution only etches lattice strained defects while not etching crystallographically perfect silicon. Table 1 shows data that compares highly defected and lightly defected thin film photovoltaic devices on various substrates with measured resistivities of 0.6, 0.14, 0.016, and 0.0035 ohm cm. Defect density was controlled by varying deposition temperature. All other fabrication processes were identical. FIG. 7 shows the surface of a preferentially defect etched sample with low defect density. FIG. 8 shows the surface of a preferentially defect etched sample with high defect density. The high defect density samples have approximately 25 times more defects than the low defect density samples.

The data shows no difference in Voc between low and high defect density devices on substrates with 0.6 ohm cm and 0.14 ohm cm resistivity. While both of these devices exhibit minimal impact of defect density on Voc, note that the devices fabricated on the 0.6 ohm cm substrate exhibit a voltage drop of approximately 50 mV. This substrate falls out of the preferred resistivity range not only because of this performance drop but also because it falls into the range of high purity, high cost substrates typically used by the solar and semiconductor industry.

Devices on substrates with a lower resistivity than 0.02 ohm cm (0.016 and 0.0035 ohm cm), exhibit a drop in Voc related to higher defect density. Devices on 0.016 ohm cm substrates exhibit a median Voc 20 mV lower on the high defect density samples compared to the low defect density samples. Devices on 0.0035 ohm cm substrates exhibit a median Voc 96 mV lower on the high defect density samples compared to the low defect density samples. This indicates a trend that as the resistivity of the substrate decreases below 0.02 ohm cm, the negative impact of defects increases as seen by the decrease in Voc. Thus thin film photovoltaic devices on substrates with resistivity over 0.02 ohm cm exhibit “fault tolerance” while devices using substrates below 0.02 ohm cm do not.

TABLE 1

| Substrate | | |
|---|---|---|
| Resistivity | Defect | Median |
| (Ω cm) | Density | V_{oc} (V) |
| 0.6 | Low | 0.559 |
| 0.6 | High | 0.562 |
| 0.14 | Low | 0.612 |
| 0.14 | High | 0.611 |
| 0.016 | Low | 0.593 |
| 0.016 | High | 0.573 |
| 0.0035 | Low | 0.594 |
| 0.0035 | High | 0.498 |

### EXAMPLE 3

This example demonstrates the use of Si Epitalixial Laterial Overgrowth (ELO) as a means of creating a buried reflector at the junction area between the substrate and the N-type thin film epitaxial layer such as demonstrated in examples 1 and 2. This approach improves the light trapping optics of the cell and reduces recombination at the epitaxial silicon/substrate interface. In this example, laser patterning is employed as a potential cost-effective method to pattern the isolator-reflector layer before the silicon ELO deposition.

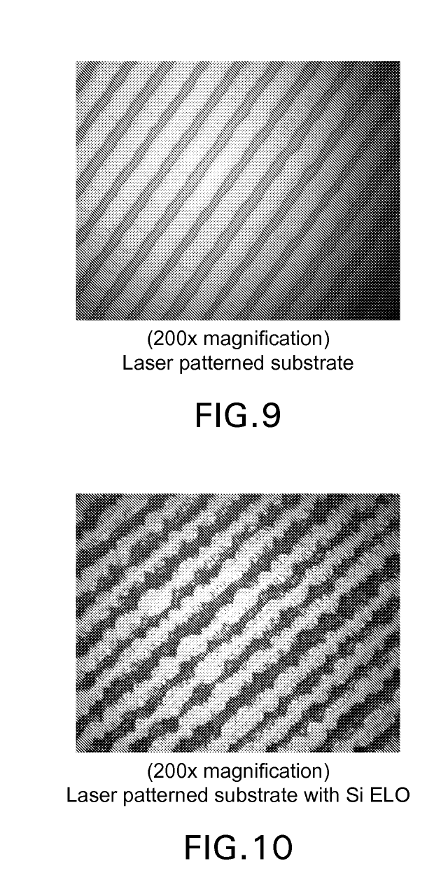

The buried reflector was created by coating a P-type substrate (resistivity: 0.1 ohm cm) with a thin SiNx layer of under 1000 angstroms, via Plasma Enhanced Chemical Vapor Deposition. A frequency-doubled Nd-YAG laser was then used to remove the SiNx layer and create line patterns. The lines were approximately 20 microns apart as shown on the photo (FIG. 9). Subsequently, an N-type ELO layer was created via silicon chemical vapor deposition, using TCS as the Si vapor source. The ELO is shown in the photo in FIG. 10.

Following the process sequence described above, the ELO surface of this intermediate device was then diffused to form a high concentration phosphorus layer to passivate the front surface (creating a high-low junction) and a back contact of aluminum was alloyed into the substrate. No evidence of extensive spontaneous nucleation was seen, which can lead to highly defected material. In contrast, most of the nucleation occurred in the patterned regions, and there appeared to be extensive lateral growth, even joining between vias in a few locations.

### EXAMPLE 4

This example describes large-area (greater than 100 sq-cm) thin epitaxial silicon solar cells fabricated on low purity, low cost multi-crystalline substrates formed through directional solidification of Upgraded Metallurgical Grade (UMG) silicon. The epitaxial silicon was deposited using Chemical Vapor Deposition (CVD) The conversion efficiency of this cell measured 11.71% at one-sun equivalent intensity. The open-circuit voltage obtained is 0.597 V, short-circuit current density is 24.64 mA/sq-cm, and fill factor is 77.7%.

Solar cells were fabricated on large-area substrates that are representative of low-cost UMG material. The substrates were P-type, multi-crystalline silicon wafers formed by directional solidification of molten silicon with a bulk resistivity of approximately 0.05 Ohm-cm. Before being used for epitaxial silicon deposition the substrate wafers were etched in a sodium hydroxide etch solution to remove mechanical saw damage. Sodium hydroxide was neutralized using a dilute solution of HCl and H2O. Dilute HF was used to remove the thin native oxide (SiO2) layer from the surface of the substrate.

A thin film of epitaxial silicon was deposited onto these substrates using an Atmospheric Pressure Chemical Vapor Deposition (APCVD) process with trichlorosilane (TCS) as the silicon containing gas in H2 diluent gas at 760 Torr and 1200 Degrees Celsius. Low concentration PH3 dopant gas was used to tune the resistivity of the epitaxial thin film to approximately 1 ohm cm. Thickness of the thin film was measured as 20 microns.

The epi-silicon wafers were then diffused with phosphorus to reduce the lateral resistance and to “passivate” the top surface. A single-layer SiNx antireflection coating was then deposited and screenprinted silver contact metallization was fired through the coating. Aluminum was alloyed onto the back surface in the same firing sequence to make contact to the substrate. To reduce contact resistance of the front contacts, the completed cells were “hydrogenated” in hydrogen plasma for 30 minutes.

Applicants specifically incorporate the entire contents of all cited references in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

What is claimed:

1. A photovoltaic device having a front and back orientation and comprising:
a crystalline substrate having a resistivity of greater than about 0.02 ohm-cm to 2 ohm-cm;
and an epitaxial thin-film layer in front of said substrate, said thin-film layer contacting said substrate in at least one region to define a p-n junction.

2. The device of claim 1, wherein said substrate has a resistivity of about 0.05 to about 0.2 ohm-cm.

3. The device of claim 1, wherein said substrate is multi-crystalline, p-type silicon and said thin-film layer is n-type silicon.

4. The device of claim 1, wherein said substrate is mono-crystalline, p-type silicon and said thin-film layer is n-type silicon.

5. The device of claim 1, wherein said substrate comprises about 1-20 ppm boron.

6. The device of claim 5, wherein said substrate is silicon with a purity of no greater than 99.99 wt %.

7. The device of claim 1, wherein said substrate has a thickness of at least about 50 μm.

8. The device of claim 1, wherein said thin-film layer has a thickness of no greater than about 50 microns.

9. The device of claim 1, further comprising:
a barrier layer between said substrate and said thin-film layer, wherein said barrier layer covers a majority of said substrate and defines at least one via, said at least one via being said at least one region.

10. The device of claim 9, wherein said at least one via comprises periodic vias through said barrier layer.

11. The device of claim 10, wherein said periodic vias are a plurality of parallel stripes orientated at a 45 degree angle to the cleave plane of the substrate, and spaced at a distance of approximately twice the height of said thin-film layer.

12. The device of claim 9, wherein said barrier is a reflector for reflecting photons away from said substrate and back into said thin-film layer.

13. The device of claim 9, wherein said reflector is an insulator.

14. A method of producing a cell comprising:
(a) providing a crystalline substrate having a resistivity of about 0.02 to about 2 ohm-cm; and
(b) epitaxially depositing a thin-film layer over at least a portion of said substrate.

15. The method of claim 14, wherein said depositing is performed using chemical vapor deposition.

16. The method of claim 14, wherein said substrate has a resistivity of about 0.05 to about 0.2 ohm-cm.

17. The method of claim 14, wherein said substrate is multi-crystalline, p-type silicon and said thin-film layer is n-type silicon.

18. The method of claim 14, wherein said substrate is mono-crystalline, p-type silicon and said thin-film layer is n-type silicon.

19. The method of claim 18, wherein said substrate is doped with boron at a concentration of about 1 to about 20 ppm.

20. The method of claim 14, wherein step (a) comprising casting said substrate.

21. The method of claim 20, wherein said casting comprises texturing the front surface of said substrate.

22. The method of claim 15, wherein said thin-film layer is deposited over said substrate using chemical vapor deposition.

23. The method of claim 15, further comprising:
depositing a third layer over a portion of said substrate.

24. The method of claim 23, wherein said third layer is at least one of a barrier or a reflector.

25. The method of claim 23, wherein said third layer is a barrier and said method further comprises:
depositing a reflector over said barrier layer.

26. The method of claim 23, further comprising:
masking said third layer to define vias, said vias being parallel;
etching said third layer to form said vias; and
epitaxially depositing said thin-film layer over said substrate and third layer, wherein said vias act as seed sites on said substrate, and said thin-film is grown laterally over said third layer.

27. The method of claim 26, wherein said substrate is silicon and has a cleave, and said vias are orientated at about a 45 degree angle to said cleave.

28. The method of claim 26, wherein said vias are spaced at about twice the thickness of said thin-film layer.

29. The method of claim 23, after said thin-film layer is deposited, texturing wherein the front surface of said thin-film layer.

30. The method of claim 23, further comprising creating a p-type layer over said third layer to increase diffusion length.

31. The method of claim 23, wherein creating a p-type layer is formed by either depositing an intermediate p-type layer over said third layer, or allowing p-type impurities to diffuse into an n-type layer.

32. The method of claim 31, wherein said n-type layer is said thin-film layer.

33. The device of claim 1, wherein said substrate has a Group III A elemental impurity level of 1 to 20 ppm.

34. The device of claim 1, wherein said substrate has a Group III elemental impurity level of 1 to 20 ppm and a Group V A elemental impurity level of 1 to 20 ppm.

35. The device of claim 1, wherein said substrate has the following impurity levels:
Group III A element: 1-20 ppm;
Group V A element: 1-20 ppm;
Iron: 5 ppm or less;
Aluminum: 5 ppm or less;
Carbon: 5 ppm or less;
Oxygen: 5 ppm or less;
Chromium: 5 ppm or less;
Calcium: 5 ppm or less;
Sodium: 5 ppm or less; and
Titanium: 5 ppm or less.

36. The device of claim 1, wherein said substrate has the following impurity levels:
Group III A element: 1-20 ppm;
Group V A element: 1-20 ppm; and said substrate has at least one or more of the following additional impurity levels:
Iron: 1 ppm to 5 ppm;
Aluminum: 1 ppm to 5 ppm;
Carbon: 1 to 5 ppm;
Oxygen: 1 to 5 ppm;
Chromium: 1 to 5 ppm;
Calcium: 1 to 5 ppm;
Sodium: 1 to 5 ppm;
Titanium: 1 to 5 ppm.

37. The device of claim 1, wherein said substrate has the following impurity levels:
Group III A element: 1-20 ppm;
Group V A element: 1-20 ppm; and said substrate has at least two or more of the following additional impurity levels:
Iron: 1 ppm to 5 ppm;
Aluminum: 1 ppm to 5 ppm;
Carbon: 1 to 5 ppm;
Oxygen: 1 to 5 ppm;
Chromium: 1 to 5 ppm;
Calcium: 1 to 5 ppm;
Sodium: 1 to 5 ppm;
Titanium: 1 to 5 ppm.

38. The device of claim 1, wherein said substrate has the following impurity levels:
Group III A element: 1-20 ppm;
Group V A element: 1-20 ppm; and said substrate has at least four or more of the following additional impurity levels:
Iron: 1 ppm to 5 ppm;
Aluminum: 1 ppm to 5 ppm;
Carbon: 1 to 5 ppm;
Oxygen: 1 to 5 ppm;
Chromium: 1 to 5 ppm;
Calcium: 1 to 5 ppm;
Sodium: 1 to 5 ppm;
Titanium: 1 to 5 ppm.

39. The device of claim 38, wherein the substrate is silicon and has Group IV A elements present, and wherein said purity level of said Group IV A elements, excluding Si, is 5 ppm or less.

40. The device of claim 1, wherein said device has at least one of the following properties:
(a) Energy Conversion Efficiency: up to 23%;
(b) Open Circuit Voltage (V_{OC}): up to 780 mV;
(c) Short Circuit Current Density (J_{SC}): up to 42 mA/sq cm;
(d) Reflectance (%): up to 15%;
(e) Fill Factor: 65% to 83%; and/or
(f) Fault Tolerant.

41. The device of claim 40, wherein at least two of said properties are present.

42. The device of claim 40, wherein at least three of said properties are present.

43. The device of claim 40, wherein at least four of said properties are present.

44. The device of claim 40, wherein at least five of said properties are present.

45. The device of claim 40, wherein all said properties are present.

46. The device of claim 1, where said device has fault tolerance.

47. The device of claim 1, wherein at least one of the following properties is present:
(a) Energy Conversion Efficiency: 10% to 23%;
(b) Open Circuit Voltage (V_{OC}): 300 mV to 780 mV;
(c) Short Circuit Current Density (J_{SC}): 10 to 42 mA/sq cm;
(d) Reflectance (%): 0.5% to 15%;
(e) Fill Factor: 65% to 83%;
(f) Fault Tolerant.

48. The device of claim 1, wherein said substrate is silicon-germanium or a silicon alloy.

49. The device of claim 1, wherein said substrate is a silicon-germanium, a silicon alloy, and having a purity level no greater than 99.99 wt %.

50. The device of claim 1, wherein said substrate is a p-type substrate and is the only p-type source in the device.
